(19) United States
(12) Patent Application Publication
(10) Pub. No.: US 2024/0013635 A1
(43) Pub. Date: Jan. 11, 2024

(54) STOP REQUEST BUTTON FOR PUBLIC TRANSPORT VEHICLE

(71) Applicant: MZ Technology, Gennevilliers (FR)

(72) Inventors: Jonathan Zerad, Levallois-Perret (FR); Jean-Marc Zerad, Maison-Alfort (FR); Martin Joly, Sait-Ouen L-Aumone (FR)

(21) Appl. No.: 18/252,295

(22) PCT Filed: Nov. 9, 2021
(86) PCT No.: PCT/FR2021/051983

§ 371 Date: May 9, 2023

(30) Foreign Application Priority Data
Nov. 9, 2020 (FR) FR2011485

(51) Int. Cl. G08B 5/36; G02B 30/56

(52) U.S. Cl. CPC G08B 5/36; G02B 30/56

(57) ABSTRACT

A button, in particular, a stop request button for a public transport vehicle, comprises a body having means for connecting to a holding tube and interaction means controlling the modification of the state of an electrical signal. The body defines a hollow volume opening out through an external window. A display screen is disposed in the hollow volume, and an optical plate is positioned between the screen and the opening of the body. The optical plate forms a floating representation of the image displayed by the display screen in a direction of observation perpendicular to the external window. The body further comprises at least one light source and at least one photoelectric sensor arranged opposite one another on the periphery of the external window.

### CROSS-REFERENCE TO RELATED APPLICATIONS

This application is a national phase entry under 35 U.S.C. § 371 of International Patent Application PCT/FR2021/051983, filed Nov. 9, 2021, designating the United States of America and published as International Patent Publication WO 2022/096840 A1 on May 12, 2022, which claims the benefit under Article 8 of the Patent Cooperation Treaty to French Patent Application Serial No. FR2011485, filed Nov. 9, 2020.

### TECHNICAL FIELD

The present disclosure relates to a button for requesting the shutdown of a public transport vehicle, in particular, a bus or a shuttle. In public transport, a vehicle user may wish to stop by pressing a stop request button when approaching the next station displayed. The stop request buttons are generally distributed in the vehicles, on stanchions and handrails formed by columns extending between the floor of the vehicle and the roof of the vehicle.

Such buttons are usually in the form of a shell incorporating an electromechanical contactor. This contactor must be very robust in order to withstand intensive, sometimes abrupt use.

### BACKGROUND

US patent US20080291156A1 is known in the prior art. This document describes a user interface comprising a physical button (“the physical button 120”) and a virtual button corresponding to the image of the physical button formed by two concave mirrors The virtual button is a ‘floating’ image of a physical button 120. The image of the physical button 120 is generated by two inwardly facing concave mirrors 131-132. The movement of the physical button is controlled by a solenoid 145. The controller 195 can also move the physical button 120, either up and down, or sideways, when the attempt of touching occurs, using an actuator such as a solenoid 145. This way, the feedback appears to directly move the virtual button 110 as it is being touched.

The solution proposed in this prior art document does not allow any freedom in the configuration of the virtual button, and requires that this virtual button be the direct image of the physical button, constituting an essential element of this prior solution.

US patent US20190294299A1 is also known, describing a contactless input device, which comprises:
an image formation system of a particular type, formed by pluralities of first and second minute reflective surfaces that intersect in planar view that are positioned vertically and in respective planes,
and a display provided on one side of the optical image formation means that forms an image on the other side of the image formation means as the first real image, and optically detects an image location of an indicating means that comes into contact with the first real image.

This solution requires particular optoelectronic components, which are expensive, involving control by complex drivers. In particular, the opto-electronic component must fulfill display and detection functions, which involves expensive technology.

European patent EP0412418B1 relates to a device with a stop request button, which can be mounted on holding bars in mainly public transport means, such as buses, with a traditional electromechanical switch.

US patent US2016033776 relates to a device for displaying stereo images and not a switch.

The solutions of the prior art are not satisfactory for several reasons.

First, the mechanical switches are exposed to an imperfect environment, with dust, humidity and dirt that can degrade the quality of the electrical contacts because the sealing of these buttons is not perfect. Secondly, these mechanical switches are subjected to inevitable wear, impairing their operation over time.

Thirdly, the contact surfaces of the button constitute sources of contamination and propagation of viral particles.

### BRIEF SUMMARY

In order to remedy these drawbacks, the present disclosure relates in its most general sense to a button, in particular, a stop request button for a public transport vehicle, with a solution involving creating a virtual image displayed on a display screen and for placing an optical plate between that screen and the window. In particular, a stop request button for a public transport comprises a body defining a hollow volume opening through an external window, and an interaction means controlling the modification of the state of an electrical signal. The body further comprises a detection barrier formed by at least one light source and at least one photoelectric sensor arranged opposite the periphery of the external window. The body has means for connecting to a holding tube a display screen in the hollow volume. The body also comprises an optical plate positioned between the screen and the opening, the optical plate forming a floating representation of the image displayed by the display screen in a direction of observation perpendicular to the external window.

### BRIEF DESCRIPTION OF THE DRAWINGS

The present disclosure will be better understood from reading the following description, which refers to one non-limiting exemplary embodiment illustrated by the appended drawings, in which:

FIG. 1 shows a partial cutaway view of a button according to the present disclosure;

FIG. 2 shows a perspective view of an insert for a button according to the present disclosure;

FIG. 3 shows an enlarged view of the optical plate;

FIG. 4 shows an optical diagram illustrating operation of the button;

FIG. 5 shows a perspective view of the button;

FIG. 6 shows a perspective view of the first shell of the button; and

FIG. 7 shows a perspective view of the second shell of the button.

### DETAILED DESCRIPTION

The present disclosure aims to propose a button, intended to equip, in particular, a public transport vehicle for stop requests, that is robust, reliable and without mechanical contact. It is based on the principle of forming a floating image, in the manner of a hologram or a “Pepper's ghost,” making it possible to simulate the presence of an activation key, and upon detection of the presence of a user's finger in the area where the virtual button appears, in order to allow activation without physical contact between the user's finger and the module. This prevents wear of the button as well as the risk of contamination.

The appended figures illustrate the production of a button intended to be mounted on a stanchion (1) of a bus. It comprises a rigid body made of plastic material or optionally of cast aluminum, forming two shells (100, 200). Each of the two shells (100, 200) has two complementary semi-tubular segments (110, 120; 210, 220) defining two sleeves capable of clamping a stanchion (1) of a bus. One of the shells (200) has a hollow box (230) in its median part, inside which an insert (300) is arranged.

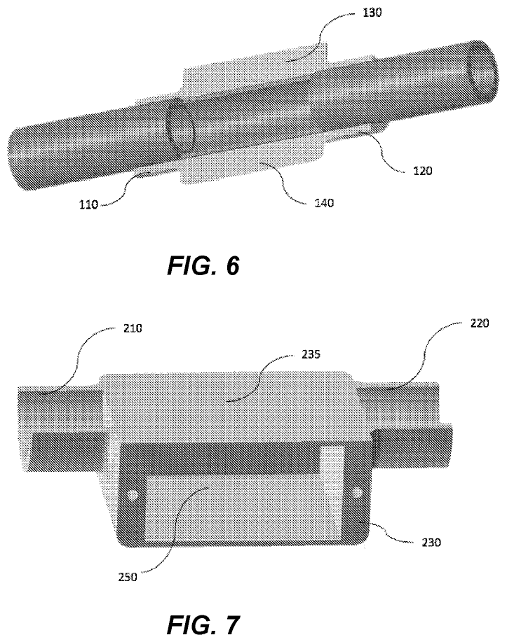

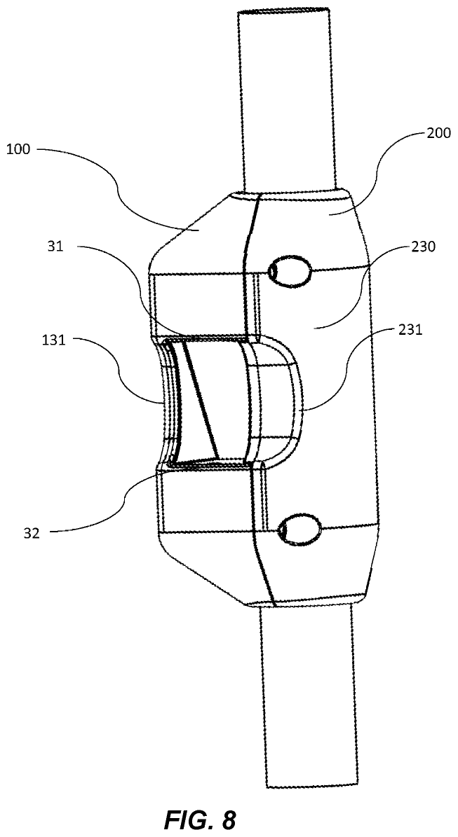

The first shell (100) has, in its median part, two lateral wings (130, 140) (FIG. 6), the upper surface of which defines a bearing plane on which one of the faces (235) (FIG. 7) of the box (230) of the second shell (200) is positioned. The box (230) opens out through a rectangular window (250) in the example described.

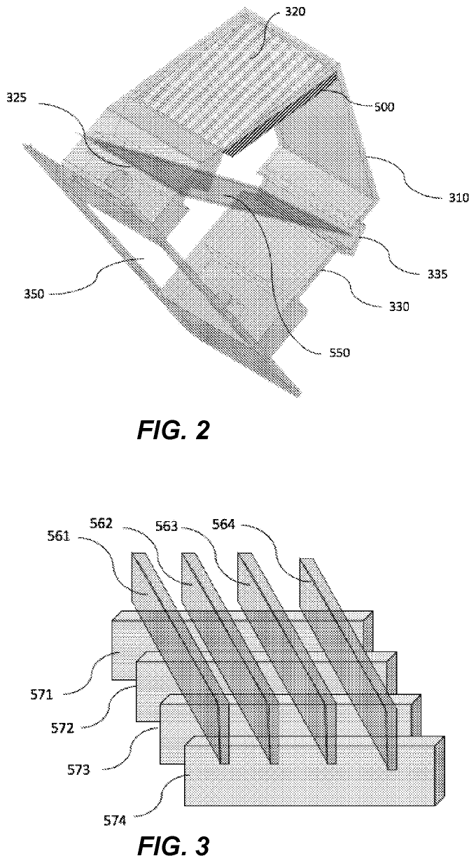

The insert (300) is a rigid part positioned in the hollow space of the box (230). The insert (300) has a dark back (310) and an inclined face (320) (FIG. 2) for receiving a display screen (500), for example, a backlit LCD screen. This back (310) is connected to the upper (320) and lower (330) faces to a front plate cut to open through a window (350). The inner surfaces of the two faces (320, 330) have transverse ribs (325, 335) for the pitch of an optical plate (550), positioned with an inclination at a median angle with respect to the angle formed between the display screen (500) and the plane of the window (350).

The optical plate (550) is formed by a reflective structure formed by a first array of reflective strips (561 to 564), parallel to one another and perpendicular to the transverse plane (560) of the optical plate (550) and a second array of reflective strips (571 to 574), parallel to each other and perpendicular to the transverse plane (560) of the optical plate (550) and oriented perpendicular to the reflective strips (561 to 564) of the first array. The pitch of these arrays is a few hundred microns.

The longitudinal slices of the reflective strips (561 to 564) of the first array are adjacent to the longitudinal slices of the reflective strips (571 to 574) of the second array, either directly or by way of an intermediate transparent strip.

The optical plate (550) is thus composed of two orthogonal specular surfaces that reflect light to project “floating” images without requiring stereoscopic glasses. The first angle of incidence and the second angle of emergence both have the same angle of reflection, and the plate acts as a projection surface for displaying images in the air at a ratio of 1:1.

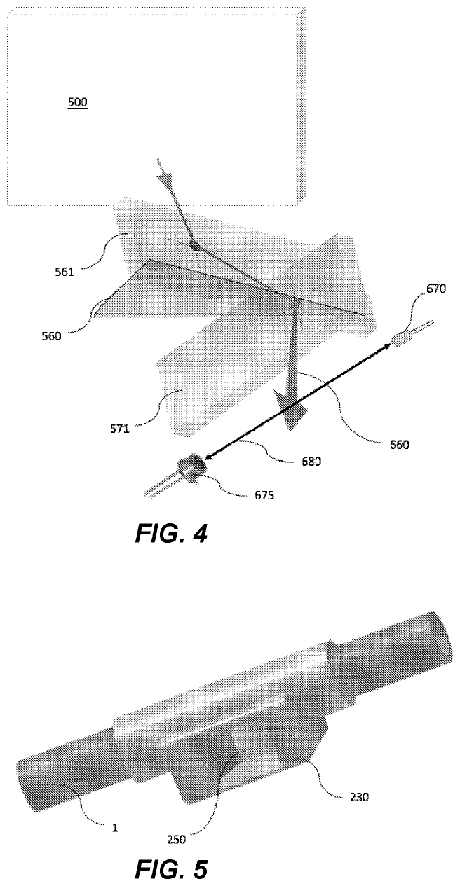

This optical plate (550) produces a floating image in the front area of the insert, corresponding to the image formed by the display screen (500), visible in the direction of observation (660) and creates the illusion of a virtual button, which could be accessed by causing the finger to penetrate through the window (350). A light barrier is formed by an LED (670) (FIG. 4) and a photodetector (675) aligned along an axis (680) formed in a plane perpendicular to the observation axis (660), and substantially parallel to the plane of the window (350). For applications with a plurality of virtual keys, it is possible to provide a plurality of offset light barriers in the plane of the window (350). It is also possible to provide for operation in the infrared.

Optionally, a protective glass is arranged in a plane parallel to the window (350), between the window and the optical plate (550) to avoid contact with this optical plate and leaving dirt.

Other shapes of optical plates that produce “floating” images may be used, for example, an optical plate composed of a plurality of two-plane cube corner reflectors with elements having two multidirectional mirrors that intersect with each other at a right angle on a transparent surface that defines a plane, the light emitted by a projected subject being reflected twice on each cube corner reflector and the reflected light being caused to penetrate through the element surface and an image of the projected subject floating in the air being formed at a position symmetrical to the plane of the projected subject (O) relative to the transparent surface.

Sensory Option

As the principle of the present disclosure involves an absence of contact between the user and a physical member, it is useful to provide a sensory element activated when an interaction is detected. It may be a sound component emitting a noise or a sound signal during the masking of the optical barrier (680), or even a vibrator. It may also be a visual signal, for example, a light-emitting diode illuminating the hollow space during the insertion of a finger into the window or else a circuit controlling the modification of the display appearing on the screen (500).

### Alternative Embodiment

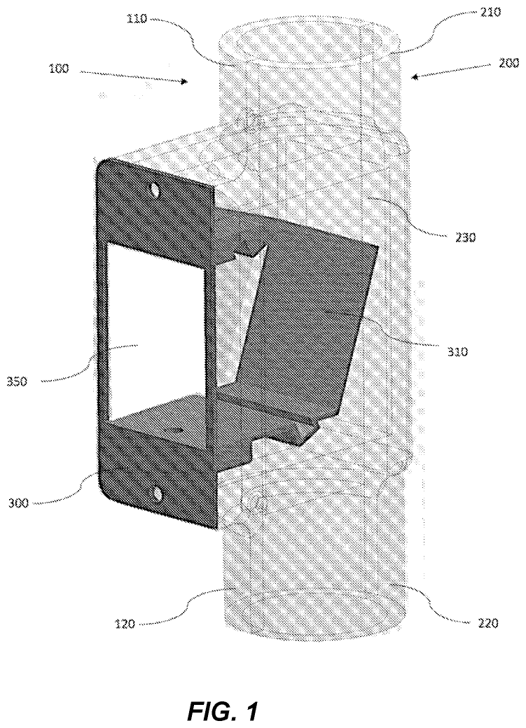

FIG. 8 shows an alternative embodiment, having all the technical features mentioned above. The embodiment of FIG. 8 is constituted, like the variant illustrated by FIG. 1, by a rigid body made of plastic material or optionally of cast aluminum, forming two shells (100, 200) assembled by screwing. The assembly of the two shells (100, 200) defines a hollow volume wherein the virtual button generated by an optical system previously described, visible by a rectangular window (250), appears.

This variant differs mainly by the presence on the two lateral faces of the shells (100, 200) of respective cut-outs (131, 231) in the form of a semi-circle allowing interaction with the virtual button not only with a finger engaged perpendicular to the plane of the window in the hollow volume, but also by an interaction with the palm or the edge face of the hand.

In this case, the light barrier detecting the penetration of an object into the window (250) is formed by a series of light sources, preferably infrared provided on an edge (31) of the window (250) perpendicular to the faces having the cut-outs (131, 231), and by detectors provided on the edge (32) of the window (250).

1. A button, comprising:
a body defining a hollow volume opening through an external window; and
an interaction means controlling modification of a state of an electrical signal;
wherein the body further comprises a detection barrier formed by at least one light source and at least one photoelectric sensor arranged opposite a periphery of the external window,
the body comprises means for connecting to a holding tube a display screen in the hollow volume,
and
the body comprises an optical plate positioned between the screen and the opening, the optical plate forming a floating representation of an image displayed by the display screen in a direction of observation perpendicular to the external window.

2. The button of claim 1, wherein the direction of observation forms an angle of between 60° and 20° to the bottom relative to the normal to the plane of the external window.

3. The button of claim 1, wherein the optical plate comprises an array of transmissive dihedral corner reflectors.

4. The button of claim 1, wherein the optical plate comprises a first array of parallel reflective strips oriented perpendicular to a median plane of the optical plate, and a second array of parallel reflective strips oriented perpendicular to the median plane of the optical plate, in a longitudinal direction different from the longitudinal direction of the reflective strips of the first array.

5. The button of claim 4, wherein the longitudinal axes of the reflective strips of the first array are perpendicular to the longitudinal axes of the reflective strips of the second array.

6. The button of claim 1, wherein the body comprises a first shell having two side wings extended longitudinally on either side by a semi-tubular channel, and a second shell including a box defining the hollow volume, a face of the second shell being complementary with the two wings of the first shell, the box being extended longitudinally on either side by a semi-tubular channel of the channels of the first shell.

7. The button of claim 1, further comprising an insert having a shape complementary to the hollow volume, the insert having a back for receiving the optical module for generating a virtual image of a button, comprising the optical plate.

8. The button of claim 1, wherein the body further comprises cut-outs on opposing sides of the external window allowing interaction with the detection barrier by interaction with the palm or the edge face of the hand.

9. The button of claim 8, wherein the detection barrier detecting the penetration of an object into the window is formed by a series of light sources provided on an edge of the window, and by detectors provided on the edge of the window.

10. The button of claim 1, wherein the button is a stop request button for a public transport vehicle.

11. A stop request button for a public transport vehicle, comprising:
a body defining a hollow volume opening through an external window to an exterior of the body; and
at least one optical device configured to generate an image within the hollow volume visible from the exterior of the body; and
a sensor configured to detect insertion of an object into the hollow volume through the external window and, in response to detecting the insertion of the object into the hollow volume, generate a stop request for the public transport vehicle.

12. The stop request button of claim 11, wherein the at least one optical device comprises a display screen configured to display an image.

13. The stop request button of claim 12, wherein the at least one optical device further comprises an optical plate configured to produce a floating image corresponding to the image displayed by the display screen.

14. The stop request button of claim 13, wherein the optical plate is oriented at an angle relative to the display screen.

15. The stop request button of claim 14, wherein the optical plate comprises a reflective structure formed by a first array of parallel reflective strips and a second array of parallel reflective strips oriented perpendicular to the parallel reflective strips of the first array.

16. The stop request button of claim 13, further comprising protective glass between the external window and the optical plate.

17. The stop request button of claim 11, wherein the sensor comprises a light barrier is formed by a light-emitting diode (LED) and a photodetector.
